(19) United States
(12) Patent Application Publication
(10) Pub. No.: US 2015/0034130 A1
(43) Pub. Date: Feb. 5, 2015

(54) METHOD OF CLEANING SEMICONDUCTOR SUBSTRATE AND APPARATUS FOR CLEANING SEMICONDUCTOR SUBSTRATE

(71) Applicant: KABUSHIKI KAISHA TOSHIBA, Minato-ku (JP)

(72) Inventors: Tatsuhiko KOIDE, Kuwana (JP); Nagisa Takami, Yokkaichi (JP); Yohei Sato, Yokkaichi (JP)

(73) Assignee: KABUSHIKI KAISHA TOSHIBA, Minato-ku (JP)

(21) Appl. No.: 14/177,579

(22) Filed: Feb. 11, 2014

(30) Foreign Application Priority Data
Aug. 5, 2013 (JP) 2013-162320

(51) Int. Cl. H01L 21/67; H01L 21/02

(52) U.S. Cl. CPC H01L 21/67023; H01L 21/02041
USPC 134/26; 134/95.3

(57) ABSTRACT

A method of cleaning a semiconductor substrate includes forming a water repellant protection film using a chemical liquid including a silane coupling agent on a surface of the semiconductor substrate; substituting the chemical liquid including the silane coupling agent with an alcohol; substituting the alcohol with a diluted alcohol; and substituting the diluted alcohol with pure water.

### CROSS-REFERENCE TO RELATED APPLICATION(S)

This application is based upon and claims the benefit of priority from Japanese Patent Application No. 2013-162320, filed on, Aug. 5, 2013 the entire contents of which are incorporated herein by reference.

### FIELD

Embodiments disclosed herein generally relate to a method of cleaning a semiconductor substrate and an apparatus for cleaning a semiconductor substrate.

### BACKGROUND

A semiconductor device manufacturing process flow involves various process steps such as lithography, etching, and ion implantation. Cleaning and drying are carried out at the end of each process step before proceeding to the subsequent process step in order to clean the wafer surface by removing impurities and residue remaining on the wafer surface.

As the devices are becoming smaller, pattern collapse may occur by capillary phenomenon when cleaning and drying the patterns formed on the wafer. One solution may be adopting a cleaning method in which the pattern surface is rendered water repellant to reduce the capillary force exerted between the patterns and the pure rinse water.

In one example of such cleaning method, the wafer surface is cleaned by chemical liquids such as SPM (sulfuric acid/hydrogen peroxide mixture) to remove the etch residues remaining on the wafer surface. Then, a rinse treatment is carried out by pure water such as DIW (deionized water) to remove the chemical liquid from the wafer. The rinse treatment is carried out by substituting the chemical liquid with pure water. Then, an alcohol rinse treatment is carried out in which pure water is substituted with alcohol such as IPA (isopropyl alcohol).

Next, a water repellant treatment is carried out on the wafer surface. The water repellant treatment is carried out by forming a water repellant protection film using, for example, a chemical liquid including a silane coupling agent. More specifically, a water repellant protection film is formed on the surface of a protrusive pattern by exposing the wafer surface to silane coupling agent. Then, alcohol rinse treatment is carried out in which the chemical liquid including the silane coupling agent is substituted with alcohol. Thereafter, a pure water rinse treatment is carried out in which the alcohol rinse liquid is substituted with pure water. Then, a dry step is carried out to remove water from the wafer. However, as the device elements become smaller, the spaces between the patterns also become narrower and thus, small amounts of chemical liquids used in the previous step were prone to remain between the patterns due to insufficient substitution often leading to pattern collapse. When a hydrophobic chemical liquid such as a silane coupling agent is used, in sufficient substitution with the hydrophilic IPA in the final water rinse caused the silane coupling agent as well as IPA to remain between the patterns which in turn caused pattern collapse from time to time.

### BRIEF DESCRIPTION OF THE DRAWINGS

FIG. 1 schematically illustrates the overall structure of a cleaning apparatus for cleaning a semiconductor substrate of a first embodiment.

FIG. 2 is a flowchart indicating the process flow of a method of cleaning a semiconductor substrate.

FIG. 3 corresponds to FIG. 2 and illustrates a second embodiment.

FIG. 4 corresponds to FIG. 2 and illustrates a third embodiment.

### DETAILED DESCRIPTION

In one embodiment, a method of cleaning a semiconductor substrate is disclosed. The method includes forming a water repellant protection film using a chemical liquid including a silane coupling agent on a surface of the semiconductor substrate; substituting the chemical liquid including the silane coupling agent with an alcohol; substituting the alcohol with a diluted alcohol; and substituting the diluted alcohol with pure water.

In one embodiment, an apparatus for cleaning a semiconductor substrate is disclosed. The apparatus includes a substrate holding and rotating mechanism holding the semiconductor substrate so as to be substantially level and rotating the held semiconductor substrate; a nozzle being disposed above a central portion of the semiconductor substrate and supplying various types of processing liquids onto the semiconductor substrate; a processing liquid supplying device feeding the various types of processing liquids to the nozzle; and a controller being configured to control the processing liquid supplying device to supply a chemical liquid including a silane coupling agent onto a surface of the semiconductor substrate, whereafter the chemical liquid including the silane coupling agent is substituted with an alcohol, whereafter the alcohol is substituted with a diluted alcohol, and whereafter the diluted alcohol is substituted with pure water.

Embodiments are described hereinafter with references to the accompanying drawings. Elements that are identical or similar are represented by identical or similar reference symbols across the embodiments and are not re-described. The drawings are not drawn to scale and thus, do not reflect the actual measurements of the features such as the correlation of thickness to planar dimensions and the relative thickness of different layers.

### First Embodiment

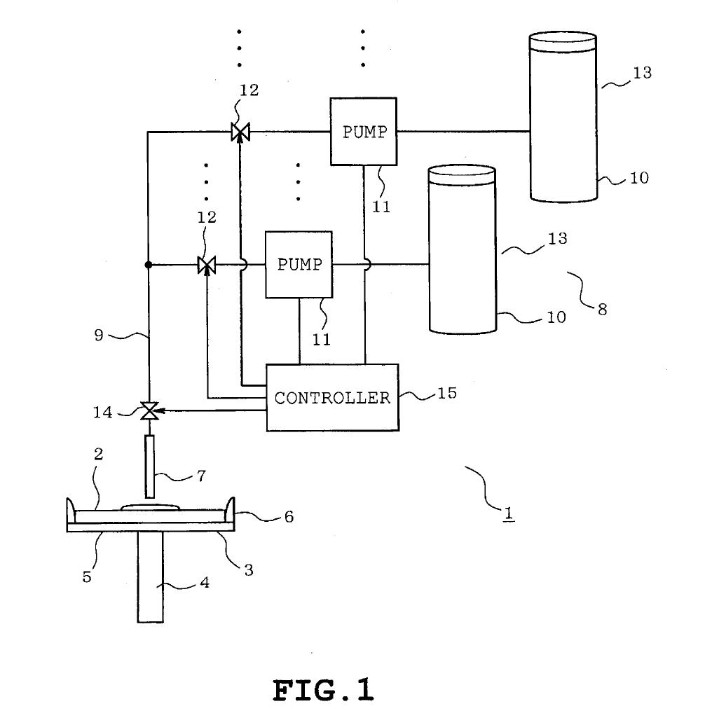

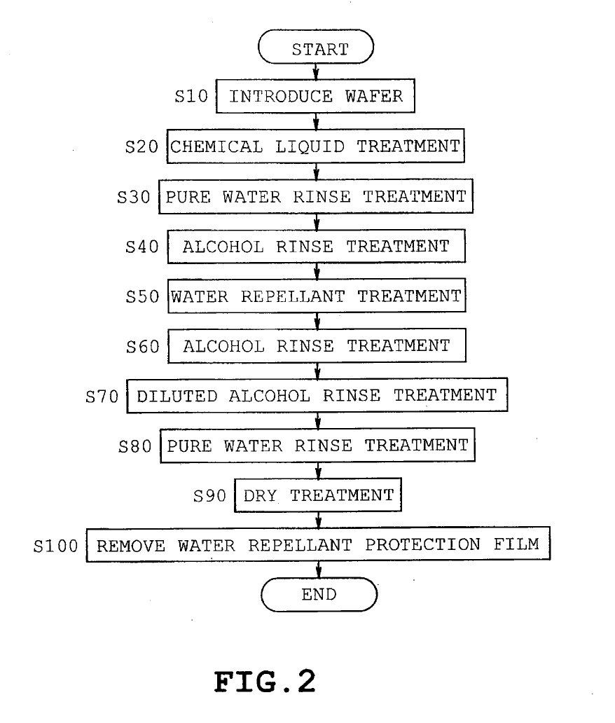

A first embodiment of a method of cleaning a semiconductor substrate and a cleaning apparatus for cleaning a semiconductor substrate will be described with reference to FIGS. 1 and 2. FIG. 1 schematically illustrates the overall structure of cleaning apparatus 1 for cleaning a semiconductor substrate. Cleaning apparatus 1 is a single wafer processing type for cleaning one wafer 2 (semiconductor substrate) at a time by supplying processing liquid onto wafer 2. As shown in FIG. 1, cleaning apparatus 1 includes spin chuck 3 which may also be referred to as a substrate holding and rotating mechanism. Wafer 2 is held so as to be substantially level and rotated by spin chuck 3. Wafer 2 to be processed is carried to spin chuck 3 by a carrier unit not shown.

Spin chuck 3 comprises rotary shaft 4, spin base 5, and chuck pin 6. Rotary shaft 4 extends substantially upright and is driven in rotation by a drive unit. Spin base is shaped like a disc and is mounted on the upper end of rotary shaft 4 for placement of wafer 2. Chuck pin 6 is disposed over the peripheral edge of spin base 5 for holding wafer 2. Spin chuck 3, holding the substantially leveled wafer 2, can be rotated at the desired speed.

Above the central portion of spin base 5 of spin chuck 3, nozzle 7 is disposed. Nozzle 7 is connected to processing liquid supplying device 8 byway of pipe 9. Processing liquid supplying device 8 supplies various types of processing liquids such as chemical liquids, pure water, and alcohol (IPA). The processing liquid fed from processing liquid supplying device 8 is discharged from the tip of nozzle 7 and supplied near the rotational center of wafer 2 surface. Nozzle 7 is preferably configured to be movable in XYZ direction by, for example, a robot.

Processing liquid supplying device 8 comprises multiple sets (equal to or greater than the number of processing liquid types) of processing liquid supplying units 13 each including tank 10, pump 11, and valve 12. Tank 10 stores the processing liquid and pump 11 feeds the processing liquid from tank 10. Valve 12 opens and closes pipe 9 through which the processing liquid flows. Valve 14 is further provided on a portion of pipe 9 near nozzle 7. Further, each of pumps 11 and valves 12 of the processing liquid supplying unit 13, as well as valve 14 are driven under the control of controller (control device) 15. Thus, controller 15 is configured to start and end the supply of multiple types of processing liquids by controlling the opening and the closing of valves 12 and 14. Controller 15 is configured to control the operation of pump 11 to increase/decrease the amount of supply of each processing liquid. Multiple nozzles 7 may be provided so that each nozzle 7 is associated with one of the multiple processing liquid supplying units 13. In such case, nozzles 7 are preferably configured to be movable in the XYZ directions by, for example, a robot and the movement of each nozzle 7 is preferably controlled by controller 15.

Next, a description will be given on a method of cleaning wafer 2 of the first embodiment.

First, at step S10 indicated in the flowchart of FIG. 2, wafer 2 is placed on spin base 5 of spin chuck 3 and is held by chuck pin 6.

Then, at step S20, chemical liquid treatment is carried out to clean the surface of wafer 2 by supplying chemical liquid such as SPM to the surface of wafer 2. Chemical liquid fed from nozzle 7 is supplied near the rotational center of wafer 2 surface. The chemical liquid spreads throughout the surface of wafer 2 by centrifugal force imparted by the rotation of wafer 2 to thereby clean wafer 2. Thus, it is possible to remove etch residues remaining on the surface of wafer 2. Though SPM is used as an example of chemical liquid in the first embodiment, SC1 which is an alkali solution of ammonia and hydrogen peroxide solution may be used instead.

Then, at step S30, pure water rinse treatment is carried out in which chemical liquid is substituted with pure water, for example, DIW (deionized water) to remove the chemical liquid from wafer 2. Pure water fed from nozzle 7 is supplied near the rotational center of wafer 2 surface. The pure water spreads throughout the surface of wafer 2 by centrifugal force imparted by the rotation of wafer 2 to thereby flush away the chemical liquid remaining on the surface of wafer 2 by pure water.

Then, at step S40, an alcohol rinse treatment is carried out in which pure water is substituted with alcohol such as IPA (isopropyl alcohol). Alcohol fed from nozzle 7 is supplied near the rotational center of wafer 2 surface. The alcohol spreads throughout the surface of wafer 2 by centrifugal force imparted by the rotation of wafer 2 to thereby substitute the pure water remaining on wafer 2 with alcohol.

Then at step S50, a water repellant treatment is carried out on the surface of wafer 2. In the water repellant treatment, a water repellant protection film is formed by using chemical liquid including, for example, a silane coupling agent. The chemical liquid including silane coupling agent fed from nozzle 7 is supplied near the rotational center of wafer 2 surface. The chemical liquid including silane coupling agent spreads throughout the surface of wafer 2 by centrifugal force imparted by the rotation of wafer 2. As a result, the silane coupling agent contacts the surface of wafer 2 to form the water repellant protection film on the surface of the protrusive pattern formed on the surface of wafer 2. The silane coupling agent preferably comprises, for example, hexamethyldisilane (HMDS) trimethylsilyldimethylamine (TMSDMA) or trimethylsilyldiethylamine (TMSDEA). The water repellant protection film may be formed by using a surface activating agent.

Next, at step S60, an alcohol rinse treatment is performed in which the chemical liquid including the silane coupling agent is substituted with alcohol such as IPA. The alcohol fed from nozzle 7 is supplied near the rotational center of wafer 2 surface. The alcohol spreads throughout the surface of wafer 2 by centrifugal force imparted by the rotation of wafer 2 to thereby substitute the chemical liquid including the silane coupling agent remaining on the surface of wafer 2 with alcohol.

Then at step S70, a diluted alcohol rinse treatment is carried out in which the alcohol rinse liquid (IPA) is substituted with diluted alcohol (diluted IPA). The diluted alcohol fed from nozzle 7 is supplied near the rotational center of wafer 2 surface. The diluted alcohol spreads throughout the surface of wafer 2 by centrifugal force imparted by the rotation of wafer 2 to thereby substitute the alcohol remaining on the surface of wafer 2 with the diluted alcohol. In one embodiment, the concentration of the diluted alcohol is, for example, approximately 50%.

Then at step S80, a pure water rinse treatment is carried out in which the diluted alcohol rinse liquid (diluted IPA) is substituted with pure water. The pure water fed from nozzle 7 is supplied near the rotational center of wafer 2 surface. The pure water spreads throughout the surface of wafer 2 by centrifugal force imparted by the rotation of wafer 2 to thereby substitute the diluted IPA remaining on the surface of wafer 2 with pure water.

As described above, by carrying out the diluted alcohol rinse treatment (step S70) in which the alcohol rinse liquid (IPA) is substituted with the diluted alcohol rinse liquid (diluted IPA) and the pure water rinse treatment (step S80) in which the diluted alcohol rinse liquid (diluted IPA) is substituted with pure water in the above described sequence, it is possible to promptly and sufficiently substitute the alcohol rinse liquid with pure water on the surface of the water repellant protection film. Conventionally, a pure water rinse treatment was carried out in which alcohol rinse liquid (IPA) was substituted directly with pure water without carrying out the above described step S70. Such pure water rinse treatment often experienced insufficient alcohol to pure water substitution and thus, suffered pattern collapse originating from residual alcohol. In contrast, the first embodiment performs the diluted alcohol rinse treatment (step S70) prior to the pure water rinse treatment (step S80) and thus, it is possible to eliminate insufficient substitution and thereby significantly reduce the risk of pattern collapse.

Then at step S90, drying treatment is carried out to remove water from wafer 2. More specifically, wafer 2 is dried, for example, by throwing off pure water remaining on the surface of wafer 2 by spin drying in which the rotation speed of wafer 2 is increased to a predetermined speed.

Then, at step S100, the water repellant protection film formed on the surface of wafer 2 is removed as required. The water repellant protection film may be removed, for example, by excimer UV treatment. Cleaning process (purifying process) of wafer 2 is thus, completed. The water repellant protection film may also be removed, for example, by dry asking or ozone gas treatment. In case the water repellant protection film is removed in the subsequent process step, the water repellant protection film need not be removed immediately after the dry treatment.

In the first embodiment, the diluted alcohol rinse treatment (step S70) and the pure water rinse treatment (step S80) are performed in the above described sequence when substituting the alcohol rinse liquid on the surface of the water repellant protection film with pure water. In the diluted alcohol rinse treatment, the alcohol rinse liquid is substituted with the diluted alcohol rinse liquid and thus, the difference in concentration of the two liquids is smaller than the difference in concentration of the two liquids when the alcohol rinse liquid is substituted directly with pure water. Because the diluted alcohol rinse liquid blends well with the alcohol rinse liquid, the alcohol rinse liquid can be substituted sufficiently with diluted alcohol rinse liquid.

In the subsequent pure water rinse treatment, the diluted alcohol rinse liquid is substituted with pure water and thus, the difference in concentration of the two liquids is smaller than the difference in concentration of the two liquids when the alcohol rinse liquid is substituted directly with pure water. Because pure water blends well with the diluted alcohol rinse liquid, the diluted alcohol rinse liquid can be substituted sufficiently with pure water. Thus, because the diluted alcohol rinse treatment and the pure water rinse treatment is carried out in the above described sequence, the alcohol rinse liquid can be substituted sufficiently with pure water as compared to the conventional direct substitution of alcohol rinse liquid with pure water.

In the first embodiment, the diluted alcohol rinse treatment is carried out using a diluted alcohol having an alcohol concentration of approximately 50%. In doing so, the diluted alcohol having the alcohol concentration of approximately 50% and being stored in tank 10 is supplied to the surface of wafer 2. Alternatively, two nozzles 7 may be provided so that IPA having approximately 100% IPA concentration is supplied from one nozzle 7 and approximately 100% pure water is supplied from the other nozzle 7 at the same time to consequently supply a diluted alcohol having an alcohol concentration of approximately 50% to the surface of wafer 2.

In the first embodiment, a diluted alcohol having an alcohol concentration of, for example, approximately 50% was used in the diluted alcohol rinse treatment (step S70). Alternatively, the diluted alcohol rinse treatment may be performed using diluted alcohol of other concentrations such as approximately 60%, 40%, or the like.

### Second Embodiment

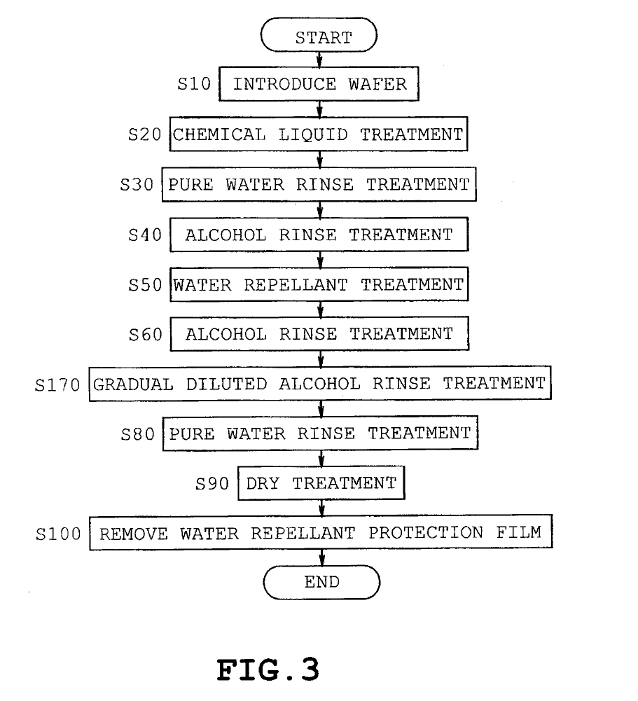

FIG. 3 illustrates a second embodiment. Elements identical to the first embodiment are identified by identical reference symbols. The cleaning method of semiconductor substrate of the second embodiment is identical to the first embodiment shown in FIG. 2 except for the gradual diluted alcohol rinse treatment of step S170 as shown in FIG. 3.

In the gradual diluted alcohol rinse treatment of step S170, the alcohol concentration of the diluted alcohol is gradually varied when supplying the diluted alcohol (IPA) near the rotational center of the surface of wafer 2 from nozzle 7. More specifically, the gradual diluted alcohol rinse treatment starts with a high alcohol concentration and gradually reduced. Preferably, the alcohol concentration is reduced in steps such as approximately 90%, 80%, . . . , and 10%.

In such case, separate processing liquid supplying units 13 are preferably provided for each concentration of diluted alcohol so that the diluted alcohol of the desired concentration can be fed to nozzle 7 by switching processing liquid supplying unit 13 to be used. Alternatively, two nozzles 7 may be provided so that alcohol having an alcohol concentration of approximately 100% is supplied from one nozzle 7 and pure water of approximately 100% is supplied at the same time from the other nozzle 7 and the ratio of supplying the approximately 100% alcohol and the approximately 100% pure water is gradually (chronologically) varied so that alcohol concentration is initially high and thereafter gradually reduced. Further alternatively, tank 10 may be provided in which alcohol having an alcohol concentration of approximately 100% and approximately 100% pure water are supplied at the same time and mixed to obtain a diluted alcohol which may be supplied to the surface of wafer 2 from a single nozzle 7. The ratio of supplying the approximately 100% alcohol and the approximately 100% pure water into tank 10 is gradually (chronologically) varied so that alcohol concentration is initially high and thereafter gradually reduced.

Besides the above, the second embodiment is identical to the first embodiment. Thus, the second embodiment obtains operation and effect which are substantially identical to those of the first embodiment. Especially because the alcohol concentration of the diluted alcohol supplied to the surface of wafer 2 from nozzle 7 is gradually varied in the second embodiment, the difference in concentration of the substituted liquids can be made even smaller. Thus, substitution of alcohol with pure water can be carried out even more sufficiently on the surface of the water repellant protection film, which in turn reduces the risk of pattern collapse originating from insufficient substitution more effectively.

### Third Embodiment

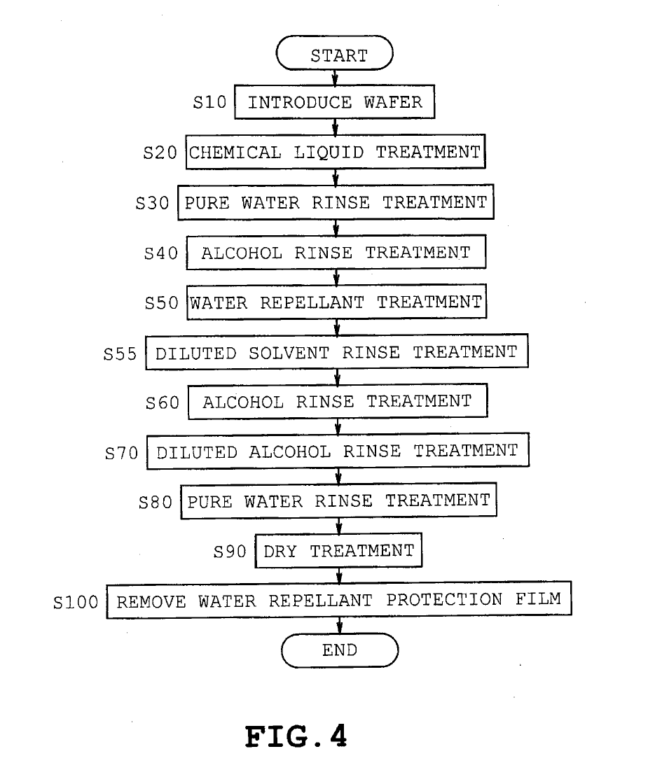

FIG. 4 illustrates a third embodiment. Elements identical to the first embodiment are identified by identical reference symbols. The cleaning method of semiconductor substrate of the third embodiment incorporates step S55 identified as diluted solvent rinse treatment between step S50 and step S60 (the alcohol rinse treatment in which the chemical liquid including silane coupling agent is substituted with alcohol) as shown in FIG. 4.

In the diluted solvent rinse treatment of step S55, a rinse treatment is executed in which the chemical liquid including silane coupling agent is substituted with a diluted solvent in which the solvent such as a thinner being used in the silane coupling agent is diluted by alcohol such as IPA. In one embodiment, the concentration of the diluted solvent is, for example, approximately 50%. An ester based, lactone based, hydrogen carbide based material, or the like is preferably used as the thinner. Examples of an ester based material include propyleneglycol monomethyl ether acetate (PGMEA) and propyleneglycol monomethyl ether (PGME). One example of a lactone based material is gamma-butyrolactone (GBL).

In step S60 following step S55, an alcohol rinse treatment for substituting the diluted solvent with alcohol is carried out.

Besides the above, the third embodiment is identical to the first embodiment. Thus, third embodiment provides the operation and effect substantially identical to those of the first embodiment. Especially in the third embodiment, the diluted solvent rinse treatment (step S55) in which the chemical liquid including silane coupling agent is rinsed by a diluted solvent obtained by diluting the solvent used in the silane coupling agent by alcohol is carried out prior to the alcohol rinse treatment in which the chemical liquid including silane coupling agent is substituted with alcohol (step S60). Thus, substitution of silane coupling agent with alcohol can be carried out even more sufficiently on the surface of the water repellant protection film, which in turn reduces the risk of pattern collapse originating from insufficient substitution more effectively.

In the third embodiment, the diluted solvent rinse treatment is carried out using a diluted solvent having a concentration of approximately 50%. In doing so, the diluted solvent having a concentration of approximately 50% and being stored in tank 10 is supplied to the surface of wafer 2. Alternatively, two nozzles 7 may be provided so that solvent (thinner) having approximately 100% solvent concentration is supplied from one nozzle 7 and alcohol having approximately 100% alcohol concentration is supplied from the other nozzle 7 at the same time to consequently supply a diluted solvent having a concentration of approximately 50% to the surface of wafer 2.

In the third embodiment, a diluted solvent having a concentration of, for example, approximately 50% was used in the diluted solvent rinse treatment (step S55). The diluted solvent rinse treatment may be performed using diluted solvent of other concentrations such as approximately 60%, 40%, or the like. Further, the concentration of the diluted solvent may be gradually varied in the diluted solvent rinse treatment (step S55). More specifically, the gradual diluted solvent rinse treatment may start, for example, with a supply of a highly concentrated diluted solvent and the concentration of the diluted solvent being supplied may thereafter be gradually reduced. In such case, it is preferable to provide two nozzles 7 so that solvent (thinner) having a solvent concentration of approximately 100% is supplied from one nozzle 7 and alcohol of approximately 100% is supplied at the same time from the other nozzle 7 and the ratio of supplying the approximately 100% solvent and the approximately 100% alcohol may be gradually varied so that solvent concentration is rendered initially high and thereafter gradually reduced. Further, alternatively, tank 10 may be provided in which the approximately 100% solvent and the approximately 100% alcohol are supplied at the same time and mixed to obtain a diluted solvent which may be supplied to the surface of wafer 2. The ratio of supplying the approximately 100% solvent and the approximately 100% alcohol into tank 10 may be gradually varied so that alcohol concentration is initially high and thereafter gradually reduced.

### Other Embodiments

The foregoing embodiments may be expanded or modified as follows.

In the foregoing embodiments, a diluted rinse treatment may be carried out prior to the substitution step preceding the water repellant protection film formation. For example, a diluted rinse treatment may be provided prior to the pure water rinse treatment of step S30 or alcohol rinse treatment of step S40. The concentration of the dilute rinse liquid of the diluted rinse treatment may be fixed, for example, to approximately 50% or gradually varied.

In the method of cleaning a semiconductor substrate described through the foregoing embodiments, it is possible to prevent collapse of microfabricated patterns during the cleaning of the surface of the semiconductor substrate in increasingly shrunk devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of cleaning a semiconductor substrate comprising:
forming a water repellant protection film using a chemical liquid including a silane coupling agent on a surface of the semiconductor substrate;
substituting the chemical liquid including the silane coupling agent with an alcohol;
substituting the alcohol with a diluted alcohol; and
substituting the diluted alcohol with pure water.

2. The method according to claim 1, wherein substituting the alcohol with the diluted alcohol employs a diluted alcohol including a fixed alcohol concentration.

3. The method according to claim 2, wherein the fixed alcohol concentration is 50%.

4. The method according to claim 1, wherein substituting the alcohol with the diluted alcohol progresses from substitution with a diluted alcohol having relatively high alcohol concentration to substitution with a diluted alcohol having a gradually reduced alcohol concentration.

5. The method according to claim 4, wherein processing liquid supplying units supplying multiple alcohol concentrations of diluted alcohol are provided, and wherein a desired alcohol concentration of diluted alcohol is selected and supplied on to the semiconductor substrate.

6. The method according to claim 4, wherein two nozzles are provided for supplying a processing liquid onto the semiconductor substrate, wherein an alcohol having an alcohol concentration of 100% is supplied from one nozzle and pure water is supplied simultaneously from the other nozzle, and
wherein a ratio of supply of the alcohol having the alcohol concentration of 100% and the pure water is gradually varied, so that concentration of alcohol is gradually reduced from a relatively high alcohol concentration to a relatively low alcohol concentration.

7. The method according to claim 4, wherein a tank is provided for mixing the alcohol having the alcohol concentration of 100% and the pure water which are supplied simultaneously to the tank to obtain a diluted alcohol, and
wherein the obtained diluted alcohol is provided onto the semiconductor substrate so that concentration of alcohol is gradually reduced from a relatively high alcohol concentration to a relatively low alcohol concentration by gradually varying the ratio of supply of the alcohol having the alcohol concentration of 100% and the pure water to the tank.

8. A method of cleaning a semiconductor substrate comprising:
forming a water repellant protection film using a chemical liquid including a silane coupling agent on the semiconductor substrate;
substituting the chemical liquid including the silane coupling agent with a diluted solvent obtained by diluting a solvent of the chemical liquid including the silane coupling agent with an alcohol;
substituting the diluted solvent with an alcohol
substituting the alcohol with a diluted alcohol; and
substituting the diluted alcohol with pure water.

9. The method according to claim 8, wherein substituting the chemical liquid with the diluted solvent employs a diluted solvent including a fixed solvent concentration.

10. The method according to claim 9, wherein the fixed solvent concentration is 50%.

11. The method according to claim 10, wherein two nozzles are provided for supplying a processing liquid onto the semiconductor substrate, wherein a solvent having a solvent concentration of 100% is supplied from one nozzle and an alcohol having an alcohol concentration of 100% is supplied simultaneously from the other nozzle, and
wherein a ratio of supply of the solvent having the solvent concentration of 100% is equalized with a ratio of supply of the alcohol having the alcohol concentration of 100% to thereby supply a diluted solvent having the solvent concentration of 50%.

12. The method according to claim 8, wherein substituting the chemical liquid with the diluted solvent progresses from substitution with a diluted solvent having a relatively high solvent concentration to substitution with a diluted solvent having a gradually reduced solvent concentration.

13. The method according to claim 8, wherein two nozzles are provided for supplying a processing liquid onto the semiconductor substrate, wherein a solvent having a solvent concentration of 100% is supplied from one nozzle and an alcohol having an alcohol concentration of 100% is supplied simultaneously from the other nozzle, and
wherein a ratio of supply of the solvent having the solvent concentration of 100% and the alcohol having the alcohol concentration of 100% is gradually varied, so that concentration of solvent is gradually reduced from a relatively high solvent concentration to a relatively low solvent concentration.

14. A cleaning apparatus for cleaning a semiconductor substrate comprising:
a substrate holding and rotating mechanism holding the semiconductor substrate so as to be substantially level and rotating the held semiconductor substrate;
a nozzle being disposed above a central portion of the semiconductor substrate and supplying various types of processing liquids onto the semiconductor substrate;
a processing liquid supplying device feeding the various types of processing liquids to the nozzle; and
a controller being configured to control the processing liquid supplying device to supply a chemical liquid including a silane coupling agent onto a surface of the semiconductor substrate, whereafter the chemical liquid including the silane coupling agent is substituted with an alcohol, whereafter the alcohol is substituted with a diluted alcohol, and whereafter the diluted alcohol is substituted with pure water.

15. The apparatus according to claim 14, wherein the diluted alcohol substituting the alcohol includes a fixed alcohol concentration.

16. The apparatus according to claim 15, wherein the fixed alcohol concentration is 50%.

17. The apparatus according to claim 14, wherein substituting the alcohol with the diluted alcohol progresses from substitution with a diluted alcohol having a relatively high alcohol concentration to substitution with a diluted alcohol having a gradually reduced alcohol concentration.

18. The apparatus according to claim 17, further comprising processing liquid supplying units containing multiple alcohol concentrations of diluted alcohol, wherein the controller is configured to select the processing liquid supplying unit containing a desired alcohol concentration of diluted alcohol and supply the diluted alcohol including the desired alcohol concentration on to the semiconductor substrate.

19. The apparatus according to claim 17, further comprising two nozzles supplying the processing liquids onto the semiconductor substrate, wherein an alcohol having an alcohol concentration of 100% is supplied from one nozzle and pure water is supplied simultaneously from the other nozzle, and
wherein a ratio of supply of the alcohol having the alcohol concentration of 100% and the pure water is gradually varied, so that concentration of alcohol is gradually reduced from a relatively high alcohol concentration to a relatively low alcohol concentration.

20. The apparatus according to claim 17, further comprising a tank for mixing the alcohol having the alcohol concentration of 100% and the pure water which are supplied simultaneously to the tank to obtain a diluted alcohol,
wherein the obtained diluted alcohol is provided onto the semiconductor substrate so that concentration of alcohol is gradually reduced from a relatively high alcohol concentration to a relatively low alcohol concentration by gradually varying the ratio of supply of the alcohol having the alcohol concentration of 100% and the pure water to the tank.
